(19) United States
(12) Patent Application Publication
(10) Pub. No.: US 2010/0154878 A1
(43) Pub. Date: Jun. 24, 2010

(54) Electrode Structure and Fabrication of the Dye-Sensitized Solar Cell

(76) Inventors: JYH-AN CHEN, HSIN-CHU (TW); SHIH-LIANG CHOU, HSIN-CHU (TW)

Correspondence Address: Jackson Intellectual Property Group PLLC, 106 Starvale Lane, Shipman, VA, 22971, US

(21) Appl. No.: 12/340,672

(22) Filed: Dec. 20, 2008

(51) Int. Cl. H01L 31/00; C23C 14/34

(52) U.S. Cl. 136/256; 204/192.17

(57) ABSTRACT

The electrode according to the invention comprises a substrate, an indium tin oxide film and a semiconductor layer and is produced under a processing condition that the substrate is subjected to ITO sputtering in a sputter chamber at a temperature of less than 200° C., preferably without being treated with heat, and then undergoes a high temperature treatment so as to form a stable ITO film. By this way, a semiconductor layer could be also formed on the indium tin oxide film. The electrode structure so produced is resistant to high temperature and has a reduced resistance change ratio. The electrode structure is especially suited for being used in a dye-sensitized solar cell to enhance the photoelectric conversion efficiency thereof.

### BACKGROUND OF THE INVENTION

(a) Field of the Invention

The present invention relates to an electrode structure and fabrication of the dye-sensitized solar cell. The invention is realized by virtue of an electrode structure which exhibits excellent and more uniform sheet resistance performance with low variation level. The electrode structure is especially suited for being used in a dye-sensitized solar cell to enhance the light-to-electrical conversion efficiency thereof.

(b) Description of the Prior Art

We have been living in the shadow of global energy crisis since last century. As the Kyoto Protocol entered into force, it becomes a global effort to search and develop alternative energy sources and solar energy application is one of the most active fields for development of new energy sources. It is estimated that the amount of energy that the Earth receives from the Sun per year is approximately one million times greater than the annual energy consumption by the people of the world. On that basis, if one hundredth of the solar energy striking the Earth's surface is converted into electricity with the conversion efficiency of 10%, it could supply enough energy which we needed.

Solar cell is a device that converts solar energy directly into electricity. In 1970s, this investigation is gradully developed since Bell Larboratories fabricated the silicon solar cell which produces electricity by the semiconductor photovoltaic effect. While the silicon solar cells exhibit great photoelectric conversion efficiency, they are difficult and expensive to fabricate and have strict with materials used. These drawbacks have precluded them from large-scale application. In 1990s, dye-sensitized solar cells were developed by the nanocrystal technologies, which are potentially a next-generation replacement for the traditional silicon solar cells and soon become a research hotspot in the related fields.

While the basic concept thereof can be traced way back to the nineteen century when photography emerged, the technology of dye-sensitized solar cells has been developing actively since a Swiss scientist, Michael Grätzel, invented in 1991 a photovoltaic cell having a photoelectric conversion efficiency of more than 7% by a nano-structured electrode material with the suitable dye. This technology successfully achieves a high efficient electron transfer interface by combining the nano-structured electrode with a dye, which is so different from the traditional material-free solid-state interfaces that the dye-sensitized solar cell may be referred to as the third generation solar cells. The dye-sensitized solar cells are characterized by low manufacture cost due to employing low cost materials, simple fabricating processes and inexpensive processing facilities, and also in possessing similar energy conversion efficiency to the conventional thin film silicon solar cells. All of these significantly reduce the manufacture cost for a dye-sensitized solar cell to around ⅕˜ 1/10 of the expense for producing a conventional silicon solar cell (depending on the fabricating processes and organic materials used). The production cost-down is strongly in favor of opening up the market for solar cells. Another advantage of dye-sensitized solar cells attributes to the semi-transparent property thereof, which makes them extremely suitable for playing a central role in the integration of construction materials (especially the window materials) for modern glass-walled skyscrapers where lighting and air conditioning demands are major components of electricity load. Dye-sensitized solar cells accomplish the functions of sunlight shielding, heat insulation and power generation at the same time, rendering the buildings equipped with the same to have dual effects on energy saving and energy generating. They are considered as one of the promising candidates for the next-generation solar cells.

The fabrication of a dye-sensitized solar cell involves applying a semiconductor layer on a transparent conductive substrate, on which a photosensitive dye is adsorbed to serve as a light sensitive layer, thereby forming a working electrode. The working principle thereof is that when dye molecules absorbs sunlight, electrons thereof become excited-state electrons and rapidly travel in the conduction bond of semiconductor layer, leaving a hole in the dye molecules. The electrons diffuses subsequently to the transparent conductive substrate and through an external electric circuit to the counter electrode. The oxidized dye molecule is reduced by an electrolyte and then the oxidized electrolyte receives electrons at the counter electrode to recover its initial state, whereby the entire procedure of electron transfer is completed. Additional advantages that a dye-sensitized solar cell may have are described below.

1. The photosensitive particles coated on the working electrode are only a few microns in thickness. These nano-scale particles are so distributed as to form a stalactite-like fractal structure, which renders the effective light receiving surface area of the light sensitive layer one-hundred times greater than the surface area of the electrode. Therefore, the solar cell may achieve high efficiency for light absorption by using rather slight amount of materials.

2. The photosensitive particles can be easily and cost-effectively manufactured by immersing semiconductor particles in the dye-containing solution for about 20 minutes and drying the particles with inert gas. There is no particular requirement for the surface roughness of the coated working electrode.

3. Dye molecules normally have broad absorption spectra in the visible region that cover a wavelength range from ten up to a hundred nanometers (the visible region extends from 400 nm to 700 nm in wavelength with an interval of around 300 nm) and, therefore, meet the requirement for capturing energy from a broad spectrum of sunlight by way of the same component.

4. In quantum efficiency terms, dye-sensitized solar cells are extremely efficient in absorbing photons from the sunlight. Quantum efficiency refers to the average number of electrons produced in the semiconductors when photons are absorbed by dye molecules. There have been found a lot of dye/semiconductor combinations so far, many of them possessing quantum efficiency of nearly 100%. It may therefore conclude that a dye-sensitized solar cell is potentially to have minimal energy loss during the conversion of light to electricity.

The transparent conductive substrate plays a critical role in a dye-sensitized solar cell. In general, a useful transparent conductive substrate should exhibit a resistivity of less than 1×10⁻³ Ω-cm and a visible light transmittance of more than 80%. The transparent conductive substrate is typically made of, for example, fluorine-doped tin oxide (SnO₂:F; FTO) or indium tin oxide (ITO) In addition to possessing low resistivity and high transparency, the transparent conductive substrate useful for a dye-sensitized solar cell should be able to tolerate an elevated temperature (above 500° C.), so that a semiconductor layer can be formed on the transparent conductive substrate using high-temperature sintering (carried out at a temperature of about 450˜500° C.). The transparent conductive substrates made of FTO, however, may possess unsatisfactory transparency and quite unstable resistance subsequent to the high temperature treatment. While the FTO-based substrates have a drawback of inconstant photoelectric conversion efficiency, they are still the majority of the products under development.

On the other hand, the ITO transparent conductive substrates are produced by the other processes (such as by preheating a substrate at a temperature of higher than 200° C. or by subjecting a substrate to heat treatment in conjunction with a simultaneous sputtering process or chemical treatment). Although the products so produced have better transparency, they show tremendous change in resistivity after being subjected to heat treatment and poor temperature stability and fail to meet the requirement for high photoelectric conversion efficiency.

### SUMMARY OF THE INVENTION

Accordingly, an object of the present invention is to provide a method for fabricating a durable electrode structure which exhibits excellent and more uniform sheet resistance performance with low variation level. Preferably, the electrode structure so produced is suited for being used in a dye-sensitized solar cell to enhance the photoelectric conversion efficiency thereof.

In order to achieve this object, the electrode structure according to the invention is produced under a processing condition that a substrate is subjected to ITO sputtering in a sputter chamber at a temperature of less than 200° C., preferably without being treated with heat, and then undergoes a high temperature treatment so as to form a semiconductor layer on the indium tin oxide film.

### BRIEF DESCRIPTION OF THE DRAWINGS

The above and other objects, features and effects of the invention will become apparent with reference to the following description of the preferred embodiments taken in conjunction with the accompanying drawings, in which:

FIG. 1 is a schematic diagram illustrating the first electrode according to the first preferred embodiment of the invention;

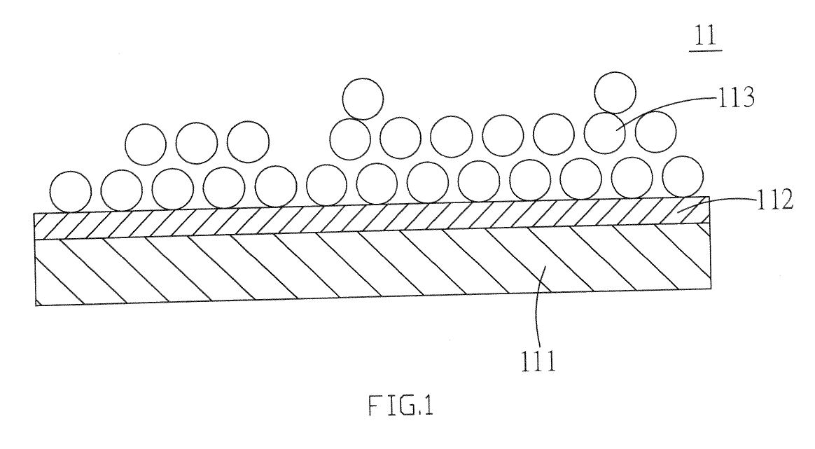

FIG. 2 is a flowchart illustrating a method for producing an indium tin oxide transparent conductive film according to the invention;

FIG. 3 is a schematic diagram illustrating the structure of a dye-sensitized solar cell according to the invention;

FIG. 4 is a schematic diagram illustrating the first electrode according to the second preferred embodiment of the invention;

FIG. 5 is a schematic diagram illustrating the first electrode according to the third preferred embodiment of the invention; and

FIG. 6 is a schematic diagram illustrating the first electrode according to the fourth preferred embodiment of the invention.

### DETAILED DESCRIPTION OF THE PREFERRED EMBODIMENTS

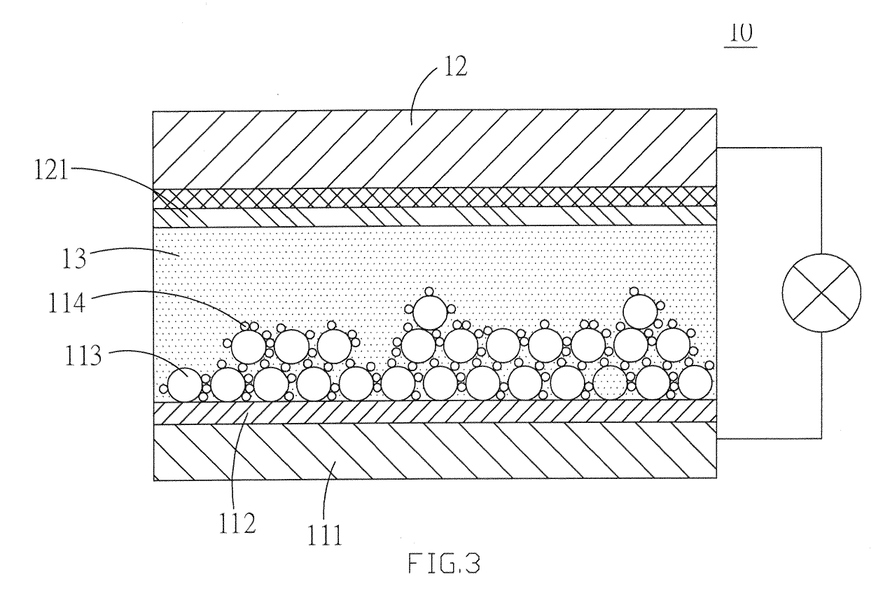

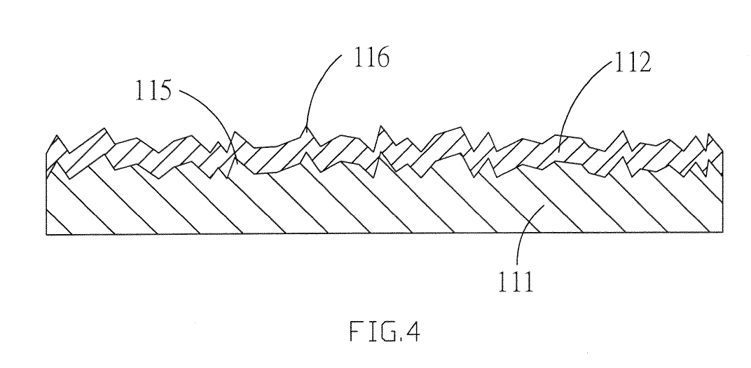

The present invention relates to a method for fabricating a durable electrode structure for a dye-sensitized solar cell which exhibits excellent and more uniform sheet resistance performance with low variation level. As shown in FIG. 3, the dye-sensitized solar cell 10 according to the invention comprises a first electrode 11 and a second electrode 12 provided oppositely to the first electrode 11. The first electrode 11 includes a substrate 111, an indium tin oxide film 112 and a semiconductor layer 113. Referring together to FIG. 4, a conductive layer 121 is provided on the second electrode 12, whereas the semiconductor layer 113 adsorbs the plurality of photosensitive dye molecules to form the photosensitive dye layer. An electrolyte 13 is provided between the conductive layer 121 and the photosensitive dye layer 114. The conductive layer 121 may be made of metal such as platinum and gold or a semiconductor material such as carbon-based semiconductor materials. The second electrode 12 may, by way of example, be made of indium tin oxide (ITO) or fluorine-doped tin oxide (FTO). The structural parts of the dye-sensitized solar cell according to the invention will be described respectively below:

(1) Electrode

The electrode is mainly a substrate (glass substrates are the most popular type of substrates available in the market according to the recent development in the industry) plated with a transparent conductive film through which electric current is conducted. A useful transparent conductive film should be so made as to meet the demands of low resistance and high transparency. However, a lower resistance means a thicker conductive film to be plated, which would result in reduced transparency and power generation efficiency. During the fabrication of a dye-sensitized solar cell, a glass substrate with great temperature stability is preferably used so as to tolerate semiconductor sintering conditions at a temperature of 450˜500° C. Therefore, the selection of materials for the transparent conductive film and the process for incorporating the transparent conductive film onto a glass substrate are critical to the photoelectric conversion efficiency of the dye-sensitized solar cell produced. The invention focuses on the way that an electrode structure is to be fabricated to meet the requirements for low electric resistance and high transparency in the dye-sensitized solar cell and further enhance the overall photoelectric conversion efficiency of the dye-sensitized solar cell.

(2) Semiconductor Layer

Titanium is the fourth abundant element present in the Earth's crust. Titanium is normally present in the form of titanium dioxide (TiO₂) in nature, with three crystalline polymorphs of rutile, anatase and brookite. The former two crystalline polymorphs are most abundant in nature and most extensively used in industry. Owing to the advantages of having stable physical and chemical properties, easiness to prepare and being free of toxicity, titanium dioxide has long been widely used in the technical fields of dyes, pigments, paintings, fillers and abrasives. Titanium dioxide is also a type of semiconductor and the application thereof has been extended to the technical fields of optoelectronic devices, sensors and alloy materials following the development of the semiconductor industry. Titanium dioxide is generally employed to serve as a semiconductor layer, taking advantage of its excellent photocatalytic activity. In the case of titanium, the bandgap between the valence band (VB) and conduction band (CB) is up to 3.0˜3.2 eV. As such, the light with higher energy than the bandgap striking titanium dioxide molecules will result in the separation of electron-hole pair. During the fabrication of the dye-sensitized solar cell, a porous titanium dioxide layer is preferably formed by coating a slurry/solution of titanium dioxide onto a substrate, followed by sintering the coated substrate. Titanium dioxide molecules primarily act as a carrier for photosensitive dyes and function to transfer electric charges. In order to extend the light transfer path in the titanium dioxide layer, the titanium dioxide layer is preferably coated with a light diffusing layer to achieve an improved effect of dye molecules carried by titanium dioxide on the absorption of light.

(3) Dye

Dye molecules are adsorbed onto titanium dioxide through acyl groups. The photoelectric conversion mechanism of a dye molecule is governed by metal to ligand charge-transfer (MLCT) transition, where d-orbital electrons of ruthenium metal (HOMO) are complexed with dye ligands (LUMO), so that the dye molecule absorbs photons to generate excited electrons and the electrons flows through titanium dioxide onto the conductive layer and the oxidized dye molecule subsequently receives electrons from the electrolyte to achieve an equilibrium state.

(4) Electrolyte

In a dye-sensitized solar cell, an electrolyte is employed to provide a redox couple. The electrolyte may therefore comprise the redox couple, solvents and additives. The most common redox couple used in a dye-sensitized solar cell comprises I₃⁻/I⁻. The solvent is employed to provide an environment friendly to ion transfer and to make the additive dissolved. Examples of the solvent include: nitrites (such as acetonitrile, methoxypropionitrile, valeronitrile and the like) and esters (such as vinyl carbonate, propylene carbonate and the like). Compared with water, these organic solvents have advantages of being inert to the electrode, not participating in the electrode reaction, having a wide electrochemical window, hardly resulting in exfoliation and degradation of dyes, having low freezing points and being useful across a broad range of temperatures. In addition, since they possess high dielectric coefficients and low viscosity, an inorganic salt can be readily solvated and dissociated therein with the resultant solutions having high electric conductivity. The additive is normally added for modifying the property of titanium dioxide to thereby improve the efficiency of a solar cell by, for example, reducing the occurrence of reverse current among titanium dioxide molecules.

(d) Conductive Layer

The conductive layer serves as a catalyst for facilitating the redox reaction between trioxide and iodide (I₃⁻/I⁻) in the electrolyte, whereby I₃⁻ is catalytically reduced to I⁻. The conductive layer is typically made of platinum, gold or carbon so as to demonstrate high catalytic activity. The conductive layer is coated on the second electrode.

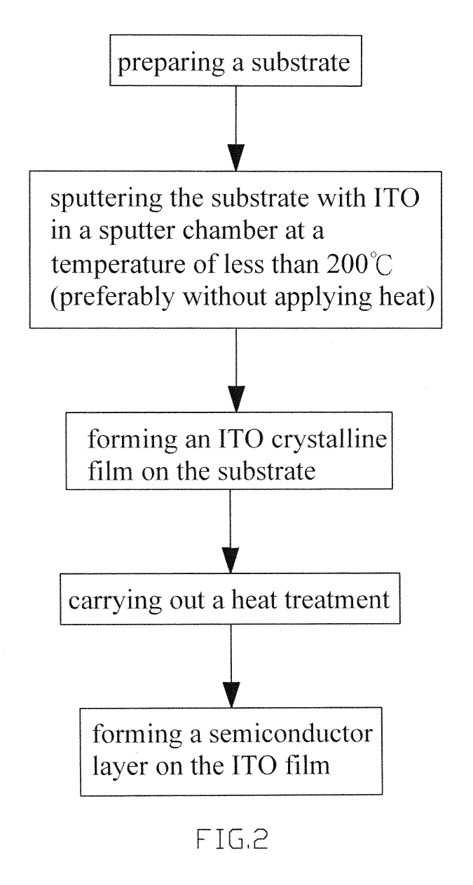

The invention provides an electrode structure which exhibits excellent and more uniform sheet resistance performance with low variation level Therefore, the electrode structure according to the invention is especially useful in the dye-sensitized solar cell. As illustrated in FIG. 2, the method for producing the first electrode may by way of example comprise the following steps.

a. A substrates which may by way of example be a transparent substrate, is prepared. The transparent substrate is preferably a glass substrate and more preferably a Soda Lim Glass-based or a Quartz Glass-based substrate.

b. An indium tin oxide (ITO) film is deposited on a surface of the substrate. The indium tin oxide film is formed under a processing condition that the substrate is sputtered in a sputter chamber at a temperature of less than 200° C., preferably without being treated with heat.

c. A heat treatment is performed wherein the substrate deposited with an indium tin oxide film undergoes a heat treatment at a particular temperature for 0.5˜3 hours (with a maximum temperature up to 550° C., normally 350° C. to 550° C.). By this ways a semiconductor layer also could be formed on the indium tin oxide film, and a finished product of the first electrode is obtained. The semiconductor layer may, by way of example, be a porous titanium dioxide layer.

As described above, the performance of the electrode structure produced by this method according the invention is hardly influenced by environmental impact, such as high temperature and high humidity, and possesses excellent sheet resistance performance with low variation level and, thus, an enhanced uniformity over the entire indium tin oxide film.

As shown in FIG. 3, the dye-sensitized solar cell that is provided with the first electrode 11 produced according to the method above further comprises the second electrode 12 provided oppositely to the first electrode 11. The first electrode 11 includes a substrate 111, an indium tin oxide film 112 and a semiconductor layer 113. A conductive layer 121 is formed on the second electrode 12, whereas the semiconductor layer 113 adsorbs the plurality of photosensitive dye molecules to form the photosensitive dye layer. An electrolyte 13 is provided between the conductive layer 121 and the photosensitive dye layer 114.

The working principle of the dye-sensitized solar cell 10 is that when a photosensitive dye molecule absorbs sunlight, electrons thereof transit to the excited state and rapidly travel to the semiconductor layer, leaving holes in the dye molecules. The electrons diffuses subsequently to the second electrode 12 and moves to the first electrode 11 via an external circuit. The oxidized dye molecules are reduced by the electrolyte and the oxidized electrolyte receives an electron from the first electrode 11 to recover its initial state, whereby the entire procedure of electron transfer is completed.

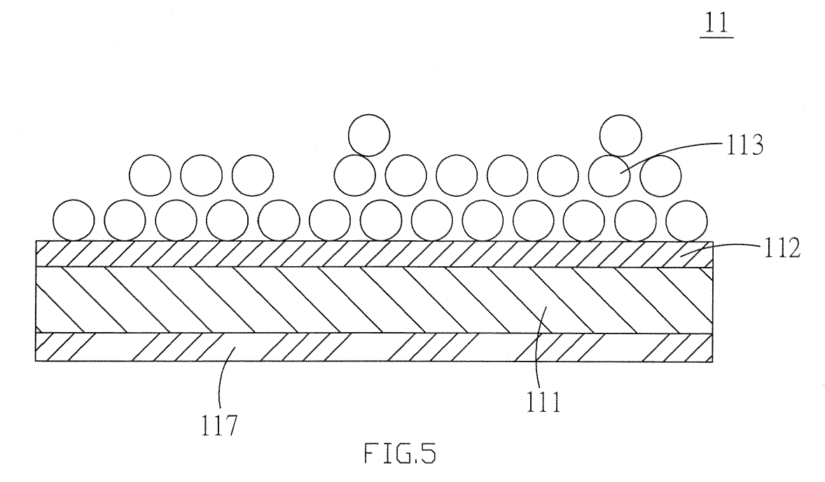

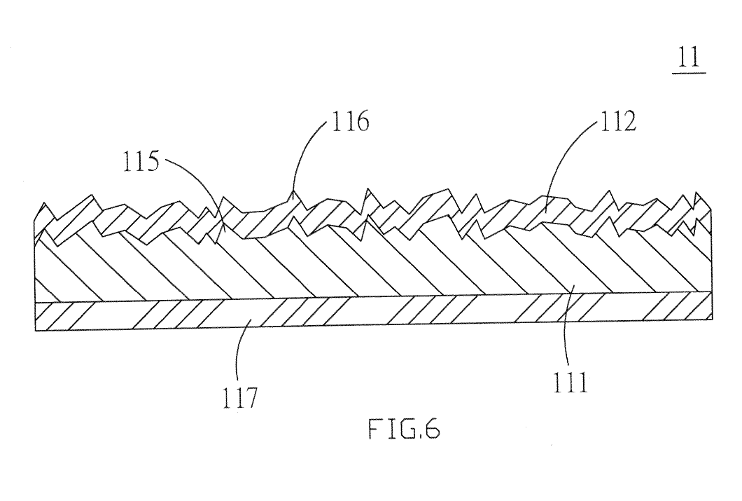

In addition, a surface of the substrate may be textured to have a plurality of first microstructures. For instance, as illustrated in FIG. 4, a plurality of first uneven microstructures 115 are formed along a surface of the substrate 111 through an etching, injection molding or atomizing process. The substrate 111 is deposited with an indium tin oxide film 112 along which second microstructures 116 are formed in correspondence with the first microstructures 115. These microstructures will increase the reactive surface area of the porous titanium dioxide layer and the photosensitive dye, thereby facilitating the photoelectric conversion. As shown in FIG. 5, an anti-reflection layer 117 may be additionally overlaid on the opposite surface of the substrate 111 to the surface on which the indium tin oxide film 112 is provided, so as to increase the light transmittance and the photoelectric conversion efficiency. Certainly, the first electrode 11 may be fabricated to have a structure shown in FIG. 6, where the second microstructures 116 and the anti-reflection layer 117 are formed on the indium tin oxide film 112 and the substrate 111, respectively.

The first electrode is preferably fabricated by the method according to the invention, whereas the second electrode may be manufactured by either a convention method or the method according to the invention. Compared with its conventional counterparts, the electrode according to the invention has the following advantages:

1. The indium tin oxide film is formed under a condition that the substrate is subjected to sputtering in a sputter chamber at a temperature of less than 200° C., preferably without being treated with heat, and then undergoes a high temperature treatment, so that the indium tin oxide film is made suited for serving as an electrode for a dye-sensitized solar cell. The indium tin oxide film so produced is hardly influenced by high temperature and high humidity (namely, good weather resistance) and possesses an enhanced uniformity over the entire indium tin oxide film (namely, an improved overall uniformity of the indium tin oxide film), a low sheet resistance variation, and high transparency. As such, the dye-sensitized solar cell provided with the electrode according to the invention exhibits an enhanced overall photoelectric conversion efficiency.

2. Compared with the ITO films made by the conventional film-coating processes, the ITO film produced by the method according to the invention has a higher degree of crystallinity, larger crystal sizes, an increased surface roughness and higher durability. Furthermore, the ITO film produced by the method according to the invention would increase the reactive surface area of the porous titanium dioxide layer and the photosensitive dye, thereby facilitating the photoelectric conversion.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit of the invention and the scope thereof as defined in the appended claims.

What is claimed is:

1. An electrode for a dye-sensitized solar cell, which is produced by a method comprising the steps of:
a. preparing a substrate;
b. sputtering the substrate with indium tin oxide in a sputter chamber at a temperature of less than 200° C., preferably without being treated with heat, to deposit an indium tin oxide film on a surface of the substrate; and
c. subjecting the semi-finished product to a heat treatment carried out at a predetermined temperature by placing the semi-finished product in or passing the semi-finished product through a heating device to form a semiconductor layer on the indium tin oxide film, whereby a finished product of the electrode is produced.

2. The electrode for a dye-sensitized solar cell according to claim 1, wherein the substrate is not subjected to preheat treatment before the step b.

3. The electrode for a dye-sensitized solar cell according to claim 1, wherein the predetermined temperature in the step c is a temperature ranging from 350° C. to 550° C.

4. The electrode for a dye-sensitized solar cell according to claim 1, wherein the heat treatment is carried out for 0.5˜3 hours.

5. The electrode for a dye-sensitized solar cell according to claim 1, wherein the substrate is selected from a transparent substrate or a glass substrate.

6. The electrode for a dye-sensitized solar cell according to claim 1, wherein the semiconductor layer is a porous titanium dioxide layer.

7. The electrode for a dye-sensitized solar cell according to claim 1, wherein the transparent electrode is used as a first electrode in the solar cell, and wherein the solar cell further comprises a second electrode on which a conductive layer is provided, and wherein the semiconductor layer adsorbs the photosensitive dye molecules to form the photosensitive dye layer, and wherein an electrolyte is provided between the conductive layer and the photosensitive dye layer.

8. The electrode for a dye-sensitized solar cell according to claim 7, wherein the second electrode is made of indium tin oxide.

9. The electrode for a dye-sensitized solar cell according to claim 7, wherein the second electrode is made of fluorine-doped tin oxide (FTO).

10. The electrode for a dye-sensitized solar cell according to claim 1, wherein the substrate has a surface textured to have a plurality of first microstructures, and wherein the indium tin oxide film is formed with a plurality of second microstructures in correspondence with the first microstructures.

11. The electrode for a dye-sensitized solar cell according to claim 1, wherein an anti-reflection layer is additionally provided on the opposite surface of the substrate to the surface on which the indium tin oxide film is provided.

12. A dye-sensitized solar cell, comprising:
a first electrode, which is the electrode according to claim 1;
a second electrode provided oppositely to the first electrode;
a photosensitive dye layer provided on the semiconductor layer;
a conductive layer provided on the second electrode; and
an electrolyte layer provided between the conductive layer and the photosensitive dye layer.

13. The dye-sensitized solar cell according to claim 12, wherein the semiconductor layer is a porous titanium dioxide layer.

14. The dye-sensitized solar cell according to claim 12, wherein the substrate has a surface textured to have a plurality of first microstructures, and wherein the indium tin oxide film is formed with a plurality of second microstructures in correspondence with the first microstructures.

15. The dye-sensitized solar cell according to claim 12, wherein an anti-reflection layer is additionally provided on the opposite surface of the substrate to the surface on which the indium tin oxide film is provided.

16. A method for producing a dye-sensitized solar cell, wherein the dye-sensitized solar cell comprises a first electrode, a second electrode, a photosensitive dye layer, a conductive layer and an electrolyte layer, and the procedure of producing a first electrode comprising:
a. preparing a substrate;
b. sputtering the substrate with indium tin oxide in a sputter chamber at a temperature of less than 200° C., preferably without being treated with heat, to deposit an indium tin oxide film on a surface of the substrate, whereby a semi-finished product is produced; and
c. subjecting the semi-finished product to a heat treatment carried out at a predetermined temperature by placing the semi-finished product in or passing the semi-finished product through a heating device to form a semiconductor layer on the indium tin oxide film, whereby a finished product of the first electrode is produced.

17. The method for producing a dye-sensitized solar cell according to claim 16, wherein the substrate is not subjected to preheat treatment before the step b carries out.

18. The method for producing a dye-sensitized solar cell according to claim 16, wherein the predetermined temperature in the step c is a temperature ranging from 350° C. to 550° C., and wherein the heat treatment is carried out for 0.5˜3 hours.

19. The method for producing a dye-sensitized solar cell according to claim 16, further comprising texturing a surface of the substrate to form a plurality of first microstructures, and forming a plurality of second microstructures along a surface of the indium tin oxide film in correspondence with the first microstructures.

20. The method for producing a dye-sensitized solar cell according to claim 16, further comprising providing an anti-reflection layer on the opposite surface of the substrate to the surface on which the indium tin oxide film is provided.
